(19) United States
(12) Patent Application Publication
(10) Pub. No.: US 2009/0026619 A1
(43) Pub. Date: Jan. 29, 2009

(54) Method for Backside Metallization for Semiconductor Substrate

(75) Inventors: Xianglin Zeng, Monterey Park, CA (US); Patty Chang-Chien, Redondo Beach, CA (US)

Correspondence Address: MILLER IP GROUP, PLC;NORTHROP GRUMMAN CORPORATION, 42690 WOODWARD AVENUE, SUITE 200, BLOOMFIELD HILLS, MI, 48304, US

(73) Assignee: Northrop Grumman Space & Mission Systems Corp., Los Angeles, CA (US)

(21) Appl. No.: 11/782,503

(22) Filed: Jul. 24, 2007

(51) Int. Cl. H01L 23/48

(52) U.S. Cl. 257/753; 257/E23.01

(57) ABSTRACT

A wafer circuit, such as a wafer-level package, that includes a semiconductor substrate on which is fabricated one or more integrated circuits. A backside metal layer is deposited on the semiconductor substrate, and is electrically coupled to the integrated circuit by metallized vias extending through the substrate wafer. The backside metal layer is cut to provide electrically isolated backside metal layers for RF, DC and/or ground signals. An adhesion layer is deposited on the backside of the substrate before the metal layer is deposited so that the metal layer is firmly secured to the substrate, and resists peeling. The adhesion layer can be sputtered silicon, sputtered silicon nitride, silicon nitride deposited by chemical vapor deposition, nickel deposited by evaporation and nickel chromium deposited by evaporation.

### BACKGROUND OF THE INVENTION

1. Field of the Invention

This invention relates generally to a semiconductor substrate including an adhesion layer and a backside metal layer and, more particularly, to a semiconductor substrate that is part of a wafer-level package that includes a backside metal layer secured to the substrate by an adhesion layer.

2. Discussion of the Related Art

It is known in the art to provide wafer-level packages for integrated circuits, such as monolithic millimeter-wave integrated circuits (MMIC), formed on substrate wafers. In one wafer-level packaging design, a cover wafer is mounted to the substrate wafer using a bonding ring so as to provide a hermetically sealed cavity in which the integrated circuits are provided. Typically, many integrated circuits are formed on the substrate wafer or the cover wafer, where one or more integrated circuits are surrounded by a separate bonding ring. The cover wafer(s) and the substrate are then diced between the bonding rings to separate the packages for each separate integrated circuit.

The semiconductor substrate that is part of a wafer-level package typically includes a backside metal layer that is electrically coupled to electrical connection points or signal traces on the integrated circuit using vias that extend through the substrate. FIG. 1 is cross-sectional view of a circuit package 10 including a semiconductor substrate 12 on which is fabricated an integrated circuit 14, such as an MMIC. A backside metal layer 16 is deposited on a backside of the semiconductor substrate 12. The backside metal layer 16 is electrically coupled to the integrated circuit 14 by a metallized via 18 extending through the substrate 12. Typically, the metal layer 16 is a gold layer. Also, the semiconductor substrate 12 may be about 100 μm thick, and the backside metal layer 16 may be about 4000 Å thick. Further, the semiconductor substrate 12 can be a group III-V semiconductor material, such as GaAs or InP.

Backside metal layers of the type described above deposited on a semiconductor substrate, such as by sputtering, have a tendency to peel off of the substrate as a result of use, oxidation, etc. Therefore, it is known in the art to provide an adhesion layer 26 deposited on the backside of the semiconductor substrate 12, and in the via hole, prior to the backside metal layer 16 being deposited on the substrate 12. The adhesion layer 26 is made of a suitable material so that it adheres well to the substrate 12 and to the metallized layer 16 so as to reduce backside metal layer peeling. Typically, the adhesion layer 26 will have a thickness of about 700 Å. Adhesion layer materials that have been used in the art include titanium (Ti), titanium/platinum (Ti/Pt), chromium and nickel valadium.

Adhesion layers are sometimes used in combination with backside metal layers for substrates that are part of wafer-level packages where the integrated circuits are provided within a hermetically sealed cavity. In these types of wafer-level package designs, as well as other types of integrated circuit fabrication, it is necessary to provide cuts through the backside metal layer 16 and the adhesion layer 26 to provide electrically isolated backside metal areas, defined here by a saw street 28. This allows various connections to the integrated circuit 14 to be provided by vias for different signals, such as RF signals, DC signals and ground, that need to be electrically isolated. The standard backside metal layer for integrated circuits was typically only a ground layer, and thus only provided a single circuit connection point to the integrated circuit. It has been shown that when the backside metal layer and the adhesion layer are sawed to define the several separate electrical connection areas, the known adhesion layer materials became less effective, and still causes unacceptable backside metal layer peeling.

### SUMMARY OF THE INVENTION

In accordance with the teachings of the present invention, a wafer circuit, such as a wafer-level package, is disclosed that includes a semiconductor substrate on which is fabricated one or more integrated circuits. A backside metal layer is deposited on the semiconductor substrate, and is electrically coupled to the integrated circuit by metallized vias extending through the substrate wafer. The backside metal layer is cut to provide electrically isolated backside metal layers for RF, DC and/or ground signals. An adhesion layer is deposited on the backside of the substrate before the metal layer is deposited so that the metal layer is firmly secured to the substrate, and resists peeling. The adhesion layer can be sputtered silicon, sputtered silicon nitride, silicon nitride deposited by chemical vapor deposition, nickel deposited by evaporation and nickel chromium deposited by evaporation.

Additional features of the present invention will become apparent from the following description and appended claims, taken in conjunction with the accompanying drawings.

### BRIEF DESCRIPTION OF THE DRAWINGS

FIG. 1 is a cross-sectional view of a wafer circuit including a backside metal layer secured to the substrate by a known adhesion layer; and

FIG. 2 is a cross-sectional view of a wafer-level package including a semiconductor substrate, where a backside metal layer is secured to the wafer substrate by a specialized adhesion layer, according to an embodiment of the present invention.

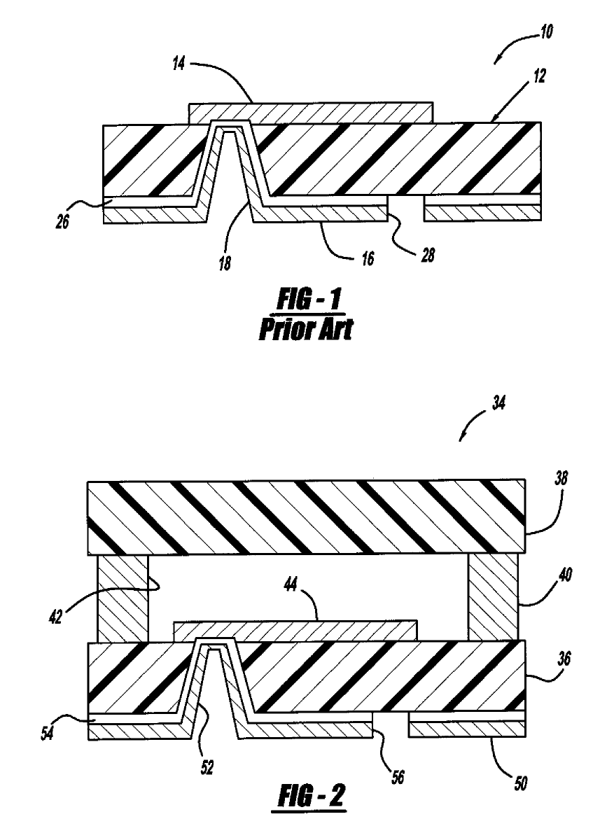

### DETAILED DESCRIPTION OF THE EMBODIMENTS

The following discussion of the embodiments of the invention directed to an adhesion layer for adhering a backside metal layer to a semiconductor substrate is merely exemplary in nature, and is in no way intended to limit the invention or its applications or uses.

FIG. 2 is a cross-sectional view of a wafer-level package 34 including a substrate wafer 36 and a cover wafer 38. The cover wafer 38 is bonded to the substrate wafer 36 by a bonding ring 40 to form a hermetically sealed cavity 42. An integrated circuit 44 that has been fabricated to a front surface of the substrate wafer 36 is sealed within the cavity 42. The cover wafer 38 can be secured to the substrate wafer 36 by a suitable bonding process. For example, a gold ring is provided on the substrate wafer 14 and an indium layer is deposited on the gold ring. A gold ring is provided on the cover wafer 38. A low temperature process is employed to melt the indium layer to form the bonding ring 40 having gold portions and an indium layer.

Although a single integrated circuit is shown formed to the substrate wafer 36, multiple integrated circuits can be provided within the cavity 42 on the substrate wafer 36 by fabrication processes well understood to those skilled in the art. Also, the cover wafer 38 can be another semiconductor wafer on which integrated circuits are formed. The integrated circuit 44 can be any suitable circuit device for wafer-level packaging, such as MMICs, filters, amplifiers, analog-to-digital converters, mixers, phase-shifters, etc. Further, the cover wafer 38 can be made of any suitable material, such as plastic, glass, aluminum, semiconductor, etc., and can have any suitable thickness. The substrate wafer 36 can be any suitable semiconductor wafer, such as group III-V semiconductors including GaAs and InP, silicon, etc. Further, the substrate wafer 36 can have any suitable thickness, such as 100 μm.

A backside metal layer 50 is deposited on a backside of the substrate wafer 36 opposite to the integrated circuit 44. The backside metal layer 50 is electrically coupled to the integrated circuit 44 by a metallized via 52 that extends through the substrate wafer 36, as shown. According to the invention, a specialized adhesion layer 54 is first deposited on the backside of the substrate wafer 36 before the metal layer 50 is deposited thereon. The adhesion layer 54 acts to firmly secure the metal layer 50 to the substrate wafer 36 so that peeling of the metal layer 50 is reduced. The adhesion layer 54 provides a good enough adhesion so that when the adhesion layer 54 and the backside metal layer 50 are sawed to provide saw streets 56 so as to define different metallized areas of the backside metal layer 50 that are electrically isolated from each other for RF signals, DC signals and ground signals, the separated portions of the backside metal layer 50 do not peel away from the substrate 36. Each separate metallized area would be electrically coupled to the integrated circuit 44 by one or more vias. Suitable materials for the backside metal layer include titanium/gold (Ti/Au), or just gold (Au).

According to the invention, the adhesion layer 54 can be one of a few different materials, can be deposited to various thicknesses, and can be deposited by various processes. For example, the adhesion layer can be silicon nitride (SiN), silicon (Si), Nickel (Ni) or Nickel Chromium (NiCr). It has been shown that silicon nitride can be deposited on the substrate wafer 36 by a sputtering process or by a 200° C. liquid phase chemical vapor deposition (LPCVD) process. In one embodiment, the sputtered silicon nitride adhesion layer has a thickness of about 2000 Å and the vapor deposition silicon nitride adhesion layer has a thickness of about 500 Å. In another embodiment, silicon can be deposited on the substrate wafer 36 by a sputtering process to a thickness of about 2000 Å. In another embodiment, the nickel and the nickel chromium adhesion layers could be deposited as an evaporated film.

The foregoing discussion discloses and describes merely exemplary embodiments of the present invention. One skilled in the art will readily recognize from such discussion, and from the accompanying drawings and claims, that various changes, modifications and variations can be made therein without departing from the spirit and scope of the invention as defined in the following claims.

What is claimed is:

1. A semiconductor circuit comprising:
a semiconductor substrate including a top surface and backside surface;
an integrated circuit formed on the top surface of the semiconductor substrate;
a metal layer deposited on the backside surface of the substrate and being electrically coupled to the integrated circuit; and
an adhesion layer deposited on the backside surface of the semiconductor substrate before the metal layer is deposited thereon so as to secure the metal layer to the substrate, said adhesion layer being selected from the group consisting of silicon layers, silicon nitride layers, nickel layers and nickel chromium layers.

2. The circuit according to claim 1 wherein the adhesion layer is a silicon layer sputtered onto the backside surface of the substrate.

3. The circuit according to claim 2 wherein the silicon layer has a thickness of about 500 Å.

4. The circuit according to claim 1 wherein the adhesion layer is a silicon nitride layer sputtered onto the backside surface of the substrate.

5. The circuit according to claim 4 wherein the silicon nitride layer has a thickness of about 2000 Å.

6. The circuit according to claim 1 wherein the adhesion layer is a silicon nitride layer deposited on the substrate by chemical vapor deposition.

7. The circuit according to claim 6 wherein the silicon nitride layer has a thickness of about 500 Å.

8. The circuit according to claim 1 wherein the adhesion layer is a nickel layer evaporated onto the backside surface of the substrate.

9. The circuit according to claim 1 wherein the adhesion layer is a nickel chromium layer evaporated on the backside surface of the substrate.

10. The circuit according to claim 1 wherein the integrated circuit is a monolithic millimeter-wave integrated circuit.

11. The circuit according to claim 1 further comprising a cover wafer sealed to the substrate and defining a cavity in which the integrated circuit is provided.

12. The circuit according to claim 1 wherein the backside metal layer is selected from the group consisting of titanium/gold layers and gold layers.

13. The circuit according to claim 1 wherein the backside metal layer is separated into electrically isolated metal portions.

14. A semiconductor circuit comprising:
a semiconductor substrate including a top surface and a backside surface;
a cover wafer mounted to the substrate and defining a hermetically sealed cavity therebetween;
an integrated circuit formed within the cavity to the semiconductor substrate or the cover wafer;
a metal layer deposited on the backside surface of the substrate and electrically coupled to the integrated circuit; and
an adhesion layer deposited on the backside surface of the semiconductor substrate before the metal layer is deposited thereon so as to secure the metal layer to the substrate, said adhesion layer being a silicon nitride layer.

15. The circuit according to claim 14 wherein the silicon nitride layer is sputtered onto the backside surface of the substrate.

16. The circuit according to claim 15 wherein the silicon nitride layer has a thickness of about 2000 Å.

17. The circuit according to claim 14 wherein the silicon nitride layer is deposited on the substrate by chemical vapor deposition.

18. The circuit according to claim 17 wherein the silicon nitride layer has a thickness of about 500 Å.

19. A semiconductor circuit comprising:
a semiconductor substrate including a top surface and a back side surface;
a cover wafer mounted to the substrate and defining a hermetically sealed cavity therebetween;
an integrated circuit formed within the cavity to the semiconductor substrate or the cover wafer;
a metal layer deposited on the backside surface of the substrate and electrically coupled to the integrated circuit; and
an adhesion layer deposited on the backside surface of the semiconductor substrate before the metal layer is deposited thereon so as to secure the metal layer to the substrate, said adhesion layer being a nickel or nickel alloy layer.

20. The circuit according to claim 19 wherein the adhesion layer is evaporated onto the backside surface of the semiconductor substrate.

21. A semiconductor circuit comprising:
a semiconductor substrate including a top surface and a backside surface;
a cover wafer mounted to the substrate and defining a hermetically sealed cavity therebetween;
an integrated circuit formed within the cavity to the semiconductor substrate or the cover wafer;
a metal layer deposited on the backside surface of the substrate and electrically coupled to the integrated circuit; and
an adhesion layer deposited on the backside surface of the semiconductor substrate before the metal layer is deposited thereon so as to secure the metal layer to the substrate, said adhesion layer being a silicon layer.

22. The circuit according to claim 21 wherein the silicon layer is sputtered onto the backside surface of the substrate.

23. The circuit according to claim 21 wherein the silicon layer has a thickness of about 500 Å.
